(19) United States
(12) Patent Application Publication
(10) Pub. No.: US 2004/0150113 A1
(43) Pub. Date: Aug. 5, 2004

(54) Semiconductor device having a Cu interconnection and method for manufacturing the same

(75) Inventor: Takashi Tonegawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 10/761,256

(22) Filed: Jan. 22, 2004

(30) Foreign Application Priority Data
Jan. 24, 2003 (JP) 2003-016700

(51) Int. Cl. H01L 21/4763; H01L 23/52; H01L 29/40; H01L 21/44

(52) U.S. Cl. 257/758; 257/762; 438/687; 438/642

(57) ABSTRACT

A Cu interconnection in a semiconductor device has an ununiform profile of additive metal atoms wherein the additive metal atoms are rich in the vicinities of bottom and side surfaces of the Cu interconnection. The Cu interconnection also has an ununiform silicon profile wherein additive silicon atoms are rich in the vicinity of the top surface of the Cu interconnection. The structure improves the electro-migration resistance and the stress-migration resistance of the Cu interconnection.

### BACKGROUND OF THE INVENTION

(a) Field of the Invention

The present invention relates to a semiconductor device having a Cu interconnection and a method for manufacturing the same.

(b) Description of the Related Art

Along with development of finer structure and higher integration density of semiconductor elements in a semiconductor device, it has become important to reduce the interconnect resistance in the semiconductor device. As one of the means to reduce the interconnect resistance, a semiconductor device having embedded Cu interconnections is introduced into practical use, wherein Cu is used as the material for the interconnections and a so-called damascene process is used for fabricating the interconnections.

It is to be noted that the interconnections should have a higher electro-migration resistance as well as the reduction of the interconnect resistance as described above. This also applies to the case of embedded Cu interconnections.

To achieve a higher electro-migration resistance, Cu alloys including additive metals such as Al and Ag are used for the Cu interconnections, as described in Patent Publications JP-A-2000-150522 and -2002-75995. In this technique, the Cu film embedded in the trench and/or via hole in an interlayer dielectric film is formed on a seed film made of a Cu alloy such as Cu—Al and Cu—Ag, or is associated with another metallic film overlying the Cu film, whereby the additive metallic atoms can be diffused into the Cu film.

It is found by the present inventor that the above technique using the seed film or the another metallic film scarcely improves a stress-migration resistance, which is also requested to the interconnections in addition to the electro-migration resistance.

More specifically, since a via is generally formed as a part of the interconnection on the top surface of an interconnection line for connecting to an overlying interconnection, a mechanical stress is applied to the contact between the via and the top surface of the interconnection line. The technique using a seed film for diffusing metallic atoms therefrom does not provide a sufficient amount of metallic atoms which reach the surface of the interconnection line. Thus, the stress applied by the via causes a void on the top surface of the interconnection line due to the movement of the minute cavities in the Cu interconnection lines. Such a void will be generated even in the structure described in Patent Publication JP-A-2000-58544 or -2000-150517, wherein the top surface of the Cu interconnection is covered with a Cu silicide layer.

On the other hand, in the technique using diffusion of the metallic atoms into the Cu interconnection through the top surface thereof for improvement of the electro-migration resistance, a void will be generated on the bottom surface of the Cu interconnection line due to the stress-migration. The void caused by the stress-migration will occur more often in the case of a larger surface area of the Cu interconnection, i.e., in the case of larger width and/or larger length of the interconnection line.

### SUMMARY OF THE INVENTION

In view of the above problems in the conventional techniques, it is an object of the present invention to provide a semiconductor device having a Cu interconnection, which is capable of suppressing the stress-migration as well as the electro-migration of the Cu interconnection.

The present invention provides a semiconductor device including a first Cu interconnection including additive metal atoms and additive silicon atoms, wherein a density of the additive metal atoms is higher in vicinities of bottom and side surfaces of the first Cu interconnection than in a vicinity of a top surface thereof, and a density of the additive silicon atoms is higher in the vicinity of the top surface than in the vicinities of the bottom and side surfaces.

In accordance with of the semiconductor device of the present invention, the Cu interconnection includes therein the additive metallic atoms and silicon atoms in the vicinities of the four surfaces of the Cu interconnection, thereby improving the electro-migration resistance and the stress-migration resistance of the Cu interconnection at the four surfaces.

The present invention also provides a method for manufacturing a semiconductor device including the steps of: forming a Cu film on top of a seed film including Cu and an additive metal; diffusing the additive metal in the seed film into the Cu film; and diffusing silicon atoms into the Cu film through a top surface thereof.

In accordance with of the method of the present invention, the Cu interconnection receives therein the additive metallic atoms and silicon atoms through the four surfaces of the Cu interconnection, thereby improving the electro-migration resistance and the stress-migration resistance of the Cu interconnection at the four surfaces.

It is to be noted that the diffusion of silicon atoms through the top surface of the Cu interconnection is totally different from the formation of a Cu silicide film on the surface of the Cu interconnection. More specifically, formation of the Cu silicide film attempts to positively cause a silicide reaction between Cu on the surface of the interconnection and silicon atoms, whereby diffusion of silicon into the Cu interconnection is suppressed by the silicide reaction. In a preferred embodiment of the method of the present invention, the silicide reaction is suppressed to allow the silicon atoms to diffuse into the Cu interconnection.

The above and other objects, features and advantages of the present invention will be more apparent from the following description, referring to the accompanying drawings.

### BRIEF DESCRIPTION OF THE DRAWINGS

FIGS. 1A to 1I are sectional views of a semiconductor device according to a first embodiment of the present invention in consecutive steps of a fabrication process therefor.

FIGS. 2A to 2I are sectional views of a semiconductor device according to a second embodiment of the present invention in consecutive steps of a fabrication process therefor.

### PREFERRED EMBODIMENTS OF THE INVENTION

Now, the present invention is more specifically described with reference to accompanying drawings, wherein similar constituent elements are designated by similar reference numerals throughout the drawings.

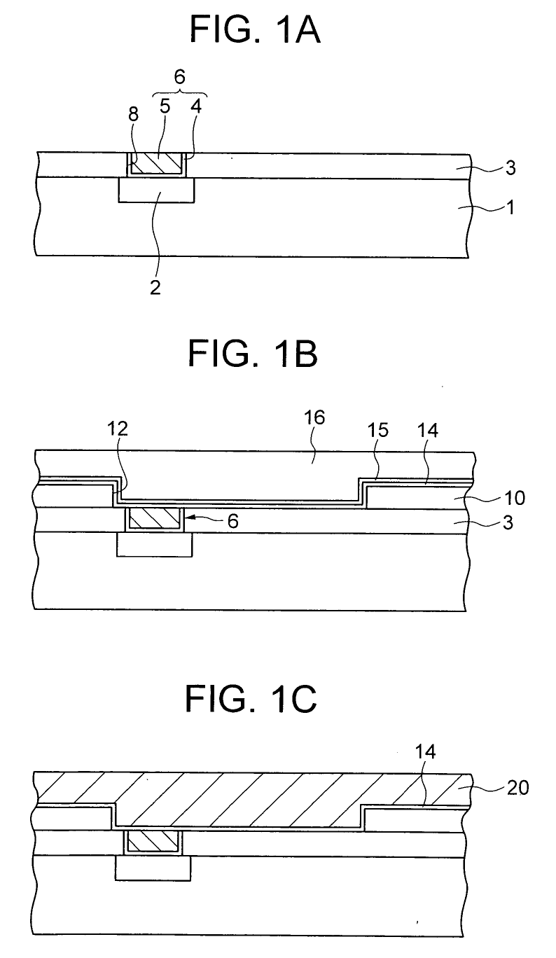

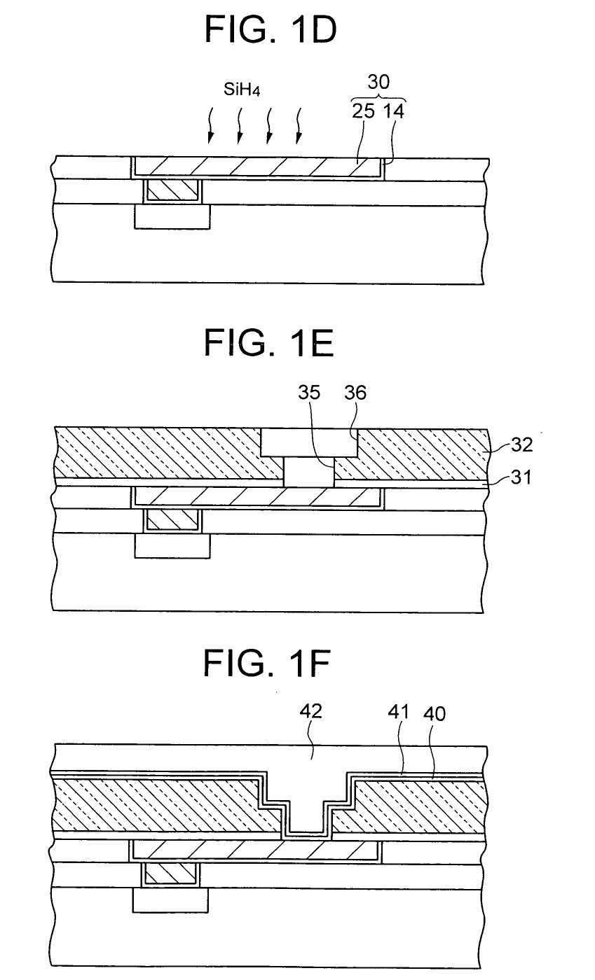

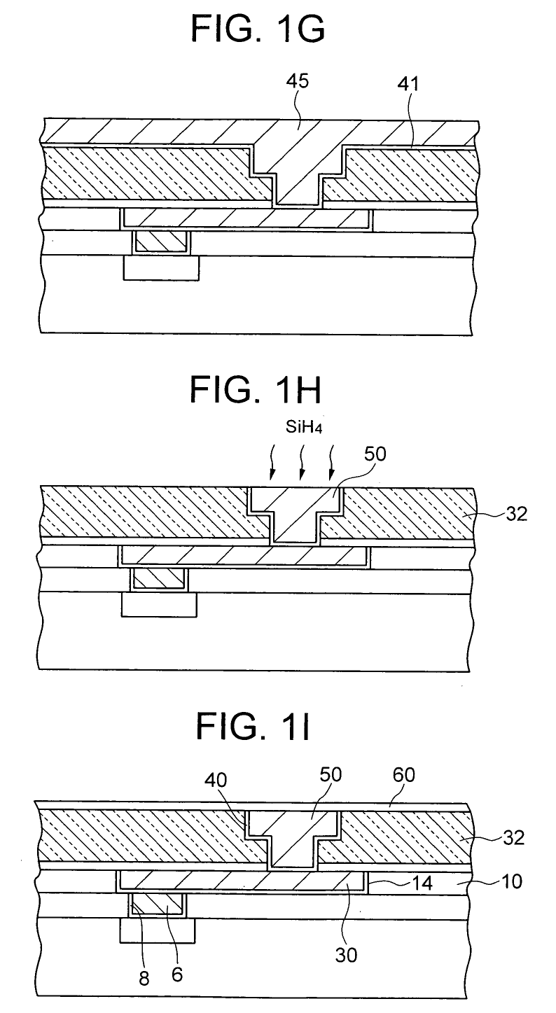

FIGS. 1A to 1I show a fabrication process for manufacturing a semiconductor device according to a first embodiment of the present invention. In FIG. 1A, a dielectric film 3 is formed on the surface of a silicon substrate 1 including therein diffused regions 2 of semiconductor elements such as transistors. The dielectric film 3 has therein a contact hole 8, which exposes therefrom the diffused region 2 on the silicon substrate 1. The contact hole 8 receives therein an embedded conductor 6. The embedded conductor 6 includes a barrier metal film 4 and a tungsten plug 5, the barrier metal film 4 having a two-layer structure including a Ti layer (not shown) on the diffused region 2 and an overlying TiN layer (not shown).

As shown in FIG. 1B, an interlayer dielectric film 10 is deposited on the dielectric film 3 and the embedded conductor 6, followed by formation of an interconnection trench 12 in the interlayer dielectric film 10. The interconnection trench 12 exposes therefrom the embedded conductor 6 and part of the dielectric film 3. Thereafter, another barrier metal film 14 having a two-layer structure including a TaN layer and an overlying Ta layer is formed on the entire surface by sputtering followed by forming a seed film 15 thereon. The seed film 15 is made of a Cu alloy including Cu and an additive metal, Al, and sputtered onto the barrier metal film 14. The Cu alloy preferably includes 0.1 to 1.5 wt % (weight percents) Al, and more preferably includes Al at a ratio not lower than 0.1 wt % and lower than 1 wt %. In this example, the Cu alloy includes 0.5 wt % Al. The additive metal, Al, may be replaced or added by one or more of other metals selected from the group consisting of Sn, Ti, Si, In, Ag, Zr, Ni, Mg, Be, Pd, Co, B, Zn, Ca, Au and Ga.

Subsequently, a Cu film 16 is deposited on the entire surface by a plating or CVD technique, as shown in FIG. 1B, followed by a thermal treatment, or annealing, at a temperature of 200 to 400 degrees C. to diffuse Al in the seed film 15 into the Cu layer 16.

Thus, a Cu alloy film 20 including therein Cu as a main component thereof and additive Al is obtained, as shown in FIG. 1C. The Cu alloy film 20 thus formed has an ununiform Al distribution, wherein the Al content decreases as viewed from the bottom surface toward the top surface of the Cu alloy film 20 and from the side surfaces toward the top surface of the resultant Cu interconnection.

Thereafter, as shown in FIG. 1D, a CMP (chemical-mechanical polishing) process, for example, is conducted to the top surface of the Cu alloy film 20, thereby obtaining a Cu interconnection 30 as the remaining parts of the Cu alloy film 20 and the underlying barrier metal film 14. Subsequently, the Cu interconnection 30 is irradiated with silane (SiH₄), with the semiconductor wafer including the Cu interconnections 30 being received in a plasma-enhanced CVD reactor. The process conditions for the silane irradiation include a silane-gas flow rate of 10 to 500 sccm (standard cubic centimeters per minute), a N₂-gas flow rate of 100 to 5000 sccm, an ambient pressure of 20 Torr, a treatment temperature of about 350 degrees C. and a treatment time of 120 seconds.

The above conditions provide suitable diffusion of silicon atoms into the Cu interconnection 30 through the top surface thereof, substantially without forming a Cu silicide layer, i.e., without involving a silicide reaction, on the top surface of the Cu interconnection 30. The diffusion of silicon atoms through the top surface of the Cu interconnection 30 provides an ununiform silicon profile within the Cu interconnection 30, wherein the silicon content decreases from the top surface toward the bottom and side surfaces of the Cu interconnection 30. The amount of additive silicon atoms is preferably 0.01 to 8 at % (atomic percents) with respect to the total of the Cu interconnection 30.

Thus, the Cu interconnection 30 has an Al profile wherein the Al content is richer in the vicinities of the bottom and side surfaces than in the vicinity of the top surface, and a silicon profile wherein the silicon content is richer in the vicinity of the top surface than in the vicinities of the bottom and side surfaces.

It is to be noted that an oxide film or any oxide should not exist on the top surface of the Cu interconnection during diffusion of silicon atoms into the Cu interconnection 30. For this purpose, it is preferable to deoxidize the oxide film or any oxide on the Cu interconnection by using hydrogen gas before the silane treatment. This deoxidization may be conducted in the plasma-enhanced CVD reactor used for the silane treatment.

Subsequently, the reactive gas in the plasma-enhanced CVD reactor is switched to a mixture of SiH(CH₃)₃, NH₃ and He, to thereby deposit a plasma-enhanced CVD SiCN film 31 on the entire surface, as shown in FIG. 1E. The deposited SiCN film 31 has a function for suppressing diffusion of Cu and may be referred to as a Cu-diffusion suppression film 31. The use of the same plasma-enhanced CVD reactor prevents the surface of the Cu interconnection 30 including the additive Al and Si atoms from being oxidized during deposition of the Cu-diffusion suppression film 31. A Cu silicide film may be formed on the Cu interconnection 30 including the additive Al and Si atoms before depositing the Cu-diffusion suppression film 31.

Thereafter, as shown in FIG. 1E, an interlayer dielectric film 32 is deposited on the Cu-diffusion suppression film 31, followed by forming a via hole 35 for receiving therein a via plug and an interconnection trench 36 for receiving therein an overlying interconnect line in the interlayer dielectric film 32 and in the SiCN film 31. This structure is known as a dual damascene structure. The dual damascene structure may be formed using via-first technique, trench-first technique, middle-first technique or dual hard-mask technique in the process of the present invention.

Thereafter, a barrier metal film 40 including Ta/TaN layers and a Cu—Al alloy seed film 41 are consecutively deposited thereon, followed by depositing a Cu film 42 by using a plating or CVD technique, as shown in FIG. 1F.

Subsequently, Al in the alloy seed film 41 is diffused into the Cu film 42 by using an thermal treatment, or annealing, thereby forming a Cu—Al alloy film 45, as shown in FIG. 1G.

A CMP process is then conducted for planarization until the Cu—Al film 45 and the barrier metal film 41 expose therefrom the dielectric film 32, thereby forming another Cu interconnection 50 including a Cu—Al alloy, as shown in FIG. 1H. The Cu interconnection 50 is then irradiated with silane similarly to the step described in connection with FIG. 1D, thereby diffusing silicon atoms in the Cu interconnection 50.

The Cu interconnection 50 thus formed has an Al profile wherein Al atoms are rich in the vicinities of the bottom and side surfaces and a silicon profile wherein silicon atoms are rich in the vicinity of the top surface. The Cu interconnection 50 includes a Cu interconnection line extending horizontally within the trench and a via plug in contact with the underlying Cu interconnection 30.

A Cu-diffusion suppression film 60 is then deposited on the entire surface including the Cu interconnection 50, as shown in FIG. 11. By iterating the steps shown in FIGS. 1E to 11, a desired number of overlying Cu interconnections can be formed.

As described above, each of the Cu interconnections 30 and 50 has an ununiform profile of Al, i.e. a metal other than Cu, wherein Al atoms are rich in the vicinities of the bottom and side surfaces, and an ununiform silicon profile wherein silicon atoms are rich in the vicinity of the top surface. This improves the electro-migration resistance of the Cu interconnections 30 and 50. In addition, the stress-migration resistance of the Cu interconnection 30 can be improved at the portion in contact with the conductor 6 in the contact hole 8, and at the portion in contact with the via plug of the overlying Cu interconnection 50. As to the Cu interconnection 50, the stress-migration resistance can be improved at the via plug and the portion in contact with an overlying Cu interconnection.

In the present embodiment, the interlayer dielectric films 10 and 32 are made of carbon-containing silicon oxide film such as SiOC or SiCOH. However, the interlayer dielectric films 10 and 32 may be instead made of silicon oxide (SiO₂), ladder-type hydrogenated siloxane (Ladder Oxide™), hydrogenated siloxane (HSQ), fluorine-containing silicon oxide (SiOF), methylsilsesquioxane (MSQ), low-dielectric-constant organic polymer such as polyphenylene, polyarylether and benzocyclobutene, and one of these insulators provided with porosity.

In the above embodiment, each of the barrier metal films 14 and 40 has a Ta/TaN two-layer structure. However, each of the barrier metal films may be instead Ta, TaN, TaSiN, W, WN, WSiN, Ti, TiN or TiSiN film, or a two- or more-layer film including a plurality of these films. The deposition of these barrier metal films may use PVD (physical vapor deposition), CVD (chemical vapor deposition) or ALD (atomic layer deposition).

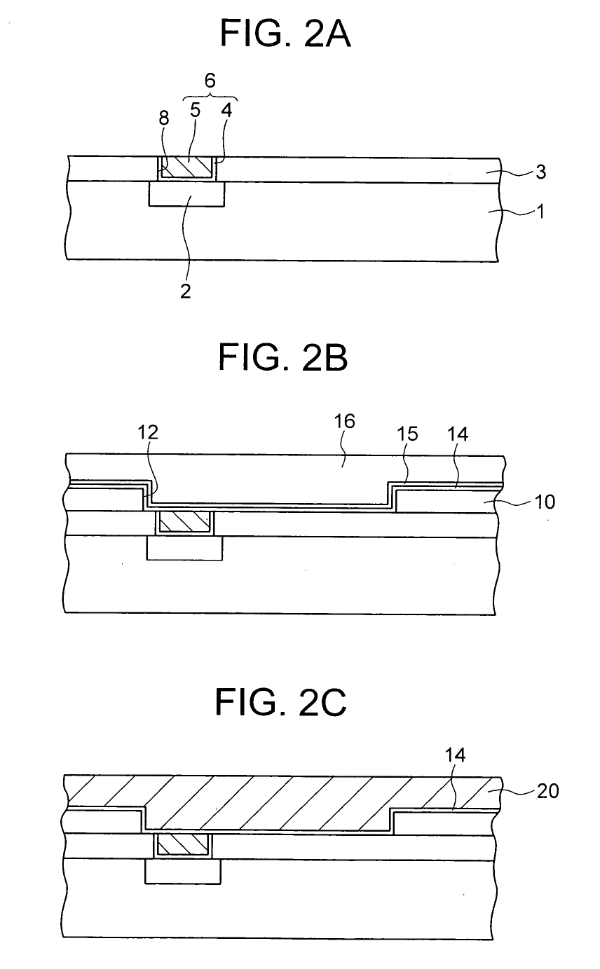

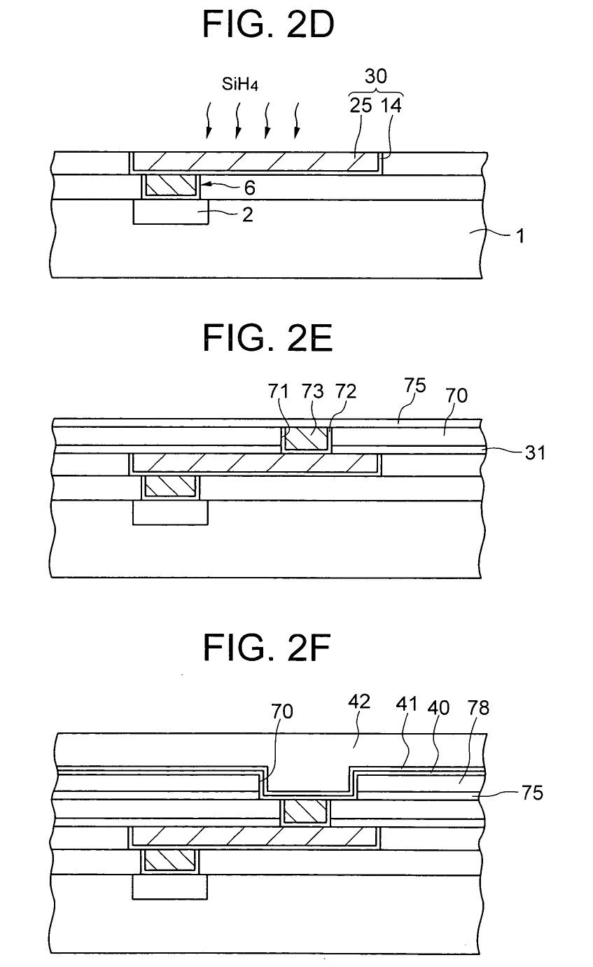

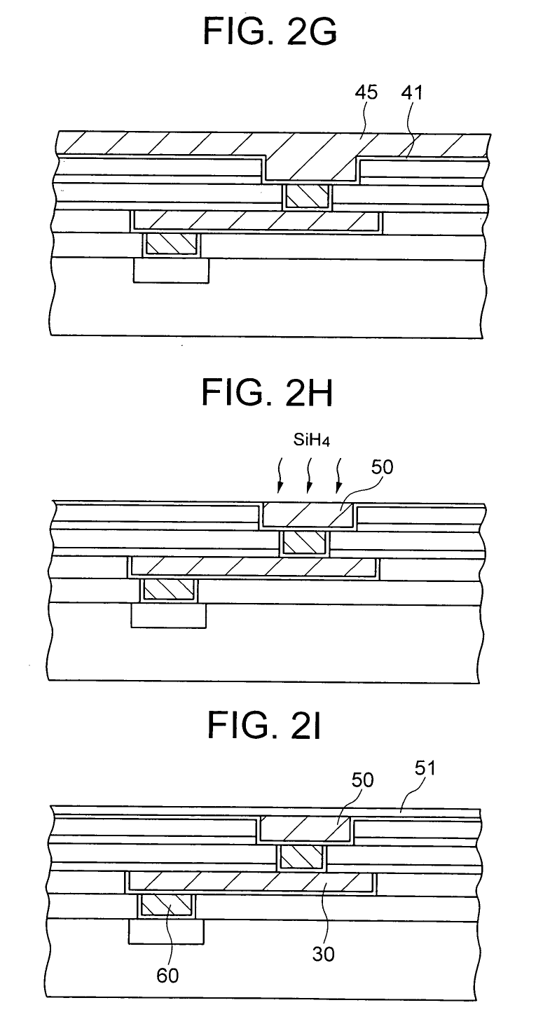

FIGS. 2A to 21 show a fabrication process for manufacturing a semiconductor device according to a second embodiment of the present invention. The present embodiment is applied to a so-called single damascene structure.

As depicted in FIGS. 2A to 2D, a conductor 6 and a first-layer Cu interconnection 30 are formed on a silicon substrate 1. The first-layer Cu interconnection 30 is connected to the conductor 6, which is in contact with the diffused region 2 formed in the silicon substrate 1.

Subsequently, as shown in FIG. 2E, a Cu-diffusion suppression film 31 and an interlayer dielectric film 70 are consecutively formed on the entire surface, followed by forming a via hole 71 used in the single damascene structure by selectively etching the Cu-diffusion suppression film 31 and the interlayer dielectric film 70. A barrier metal film 72 including Ta/TaN layers is then formed on the entire surface including the via hole 71, followed by forming consecutively a seed film (not shown) and a Cu film 73. A CMP process is then conducted to leave the Cu film 73 as well as the barrier metal film 72 and the seed film within the via hole 71. The seed film in the present embodiment is made of Cu without including any other metal such as Al. The Cu film 73 does not include therein-diffused silicon atoms. The Cu film 73 is sandwiched between the barrier metal film 72 and a Cu-diffusion suppression film 75 formed thereon, thereby having a higher electro-migration resistance as well as a higher stress-migration resistance.

Alternatively, the seed film may be made of a Cu alloy and thus may include metal atoms other than Cu, which are diffused through the top surface of the seed film to the Cu film 73. In addition, silicon atoms may be diffused into the Cu interconnection line 73 through the top surface thereof.

Thereafter, as shown in FIG. 2F, an interlayer dielectric film 78 is deposited on the entire surface, followed by forming an interconnection trench 79 for receiving therein a Cu interconnection line by selectively etching the interlayer dielectric film 78 and the Cu-diffusion suppression film 75. Thereafter, a barrier metal film 40, seed film 41 and a Cu film 42 are formed, as shown in FIG. 2F, by using the process similar to the process described in connection with FIG. 1F.

Thereafter, as shown in FIGS. 2G to 2I, a second-layer Cu interconnection 50 is formed by the process similar to the process described in connection with FIGS. 1G to 11.

In the present embodiment, the interlayer dielectric films 10, 70 and 78 are made of carbon-containing silicon oxide such as SiOC or SiCOH. However, the interlayer dielectric films 10, 70 and 78 may be instead made of silicon oxide (SiO₂), ladder-type hydrogenated siloxane (Ladder Oxide™), hydrogenated siloxane (HSQ), fluorine-containing silicon oxide (SiOF), methylsilsesquioxane (MSQ), low-dielectric-constant organic polymer such as polyphenylene, polyarylether and benzocyclobutene, and one of these insulators provided with porosity.

In the above embodiment, each of the barrier metal films 14, 72 and 40 has a two-layer structure, Ta/TaN. However, each of these barrier metal films may be instead Ta, TaN, TaSiN, W, WN, WSiN, Ti, TiN or TiSiN film, or a two- or more-layer film including a plurality of these dielectric films. The deposition of these barrier metal films may use PVD (physical vapor deposition), CVD (chemical vapor deposition) or ALD (atomic layer deposition).

In the above embodiments, the semiconductor devices have low-resistance interconnections, which have a higher electro-migration resistance and a higher stress-migration resistance.

Since the above embodiments are described only for examples, the present invention is not limited to the above embodiments and various modifications or alterations can be easily made therefrom by those skilled in the art without departing from the scope of the present invention. For example, the additive metal in the Cu alloy, the process conditions, materials used therein may be modified as desired.

What is claimed is:

1. A semiconductor device comprising a first Cu interconnection including additive metal atoms and additive silicon atoms, wherein a density of said additive metal atoms is higher in vicinities of bottom and side surfaces of said first Cu interconnection than in a vicinity of a top surface thereof, and a density of said additive silicon atoms is higher in said vicinity of said top surface than in said vicinities of said bottom and side surfaces.

2. The semiconductor device according to claim 1, wherein said additive metal atoms include atoms of one or more of metals selected from the group consisting of Al, Sn, Ti, Si, In, Ag, Zr, Ni, Mg, Be, Pd, Co, B, Zn, Ca, Au and Ga.

3. The semiconductor device according to claim 1, further comprising a second Cu interconnection overlying said first Cu interconnection and including additive metal atoms and additive silicon atoms, wherein a density of said additive metal atoms in said second Cu interconnection is higher in vicinities of bottom and side surfaces of said first Cu interconnection than in a vicinity of a top surface thereof, and a density of said additive silicon atoms in said second Cu interconnection is higher in said vicinity of said top surface than in said vicinities of said bottom and side surfaces.

4. The semiconductor device according to claim 3, wherein said additive metal atoms in said second Cu interconnection include atoms of one or more of metals selected from the group consisting of Al, Sn, Ti, Si, In, Ag, Zr, Ni, Mg, Be, Pd, Co, B, Zn, Ca, Au and Ga.

5. The semiconductor device according to claim 3, wherein said second Cu interconnection includes a Cu interconnection line and a via plug extending from said Cu interconnection line and connected to said first Cu interconnection.

6. The semiconductor device according to claim 3, wherein said first Cu interconnection and said second Cu interconnection are connected together via a Cu plug covered with a barrier metal film.

7. A method for manufacturing a semiconductor device comprising the steps of:
forming a Cu film on top of a seed film including Cu and an additive metal;
diffusing said additive metal in said seed film into said Cu film; and
diffusing silicon atoms into said Cu film through a top surface thereof.

8. The method according to claim 7, wherein said silicon atoms diffusing step comprises the step of irradiating silane onto said Cu film.

9. The method according to claim 8, wherein said irradiating step is performed after said Cu film is configured as Cu interconnections.

10. The method according to claim 7, wherein said seed film comprises said additive metal at 0.1 to 1.5 wt %.

11. The method according to claim 7, wherein said seed film comprises Al as said additive metal at a weight percent lower than 1% and not lower than 0.1%
